(19) United States
(12) Patent Application Publication
(10) Pub. No.: US 2023/0031663 A1
(43) Pub. Date: Feb. 2, 2023

(54) METHOD FOR MANUFACTURING A PHOTOVOLTAIC MODULE WITH PARTIAL CROSSLINKING AND LAMINATION

(71) Applicant: COMMISSARIAT A L'ENERGIE ATOMIQUE ET AUX ENERGIES ALTERNATIVES, Paris (FR)

(72) Inventors: Victor MANEVAL, Grenoble Cedex 09 (FR); Fabien CHABUEL, Grenoble Cedex 09 (FR); Julien GAUME, Grenoble Cedex 09 (FR); Yannick ROUJOL, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 17/785,377

(22) PCT Filed: Nov. 30, 2020
(86) PCT No.: PCT/FR2020/052221

§ 371 Date: Jun. 14, 2022

(30) Foreign Application Priority Data
Dec. 16, 2019 (FR) 1914469

(51) Int. Cl. H01L 31/048; H01L 31/18

(52) U.S. Cl. CPC H01L 31/0481; H01L 31/18

(57) ABSTRACT

The main object of the invention is a method for manufacturing a photovoltaic module, comprising at least one photovoltaic cell (4) between a first transparent layer (1) forming a front face and a second layer (2) forming a rear face, characterised in that it includes: 1) a first step of depositing a first adhesive layer based on a crosslinkable polymer material over the first layer (1) and depositing a second adhesive layer based on a crosslinkable polymer material over the second layer (2); 2) a second step of partially crosslinking the two adhesive layers; 3) a third step of depositing said at least one photovoltaic cell (4) over one (SPR1) of the two partially crosslinked adhesive layers (SPR1, SPR2); 4) a fourth step of forming a multilayer stack; 5) a fifth step of laminating the multilayer stack.

### TECHNICAL FIELD

The present invention relates to the field of photovoltaic modules, which include a set of electrically interconnected photovoltaic cells.

More specifically, the invention relates to the field of photovoltaic modules used for space applications, but also for terrestrial applications. Such photovoltaic modules may be flexible or rigid.

Thus, the invention suggests a method for manufacturing a photovoltaic module with partial crosslinking and lamination steps.

### PRIOR ART

In order to preserve the photovoltaic cells of a photovoltaic module, it is common to encapsulate them. The encapsulation of the photovoltaic cells allows protecting them from the external environment, such as for example rain, wind, snow, humidity, ultraviolet radiations, radiations, inter alia.

For this purpose, it is known to form a stack successively including: a rear protective element, a first encapsulant film, conventionally of ethylene vinyl acetate (EVA), photovoltaic cells electrically connected together, a second encapsulant film, conventionally of ethylene vinyl acetate (EVA), a transparent front protective element such as a glass plate.

The front protective element is intended to receive solar radiation before the latter cooperates with the photovoltaic cells to generate electrical energy. Afterwards, this stack is hot rolled to melt the EVA films and cause crosslinking of the molten EVA, resulting in the formation of a solid encapsulation envelope of the photovoltaic cells glued to the front and rear protective elements.

The use of EVA in a film form has the advantage of facilitating the manufacture of a photovoltaic module by using hot lamination of the stack. It is also more competitive for an industrial use. However, EVA has the drawback of generating acetic acid upon crosslinking thereof during lamination, this acetic acid causing in particular the erosion of the electrodes of the photovoltaic cells. EVA also has the drawback of yellowing over time due to its exposure to ultraviolet radiations. Moreover, EVA has the drawback of being associated with a narrow range of use temperatures which makes its use incompatible in a space environment. Finally, industrial EVA films are currently hardly available in thicknesses as small as those desired for space applications. The required thickness is smaller than 100 μm, while the films available in the industry are at least 200 μrn.

Also, encapsulation solutions based on silicones, or else polysiloxanes, have been considered in the prior art, in particular for space and terrestrial applications, as well as glue for some components of satellites.

For example, the American patent U.S. Pat. No. 4,057,439 A describes an encapsulation solution based on silicones. The objective of the patent is to improve the adhesion of such encapsulants on the solar cells and the supports to avoid delaminations. The problem with this solution is that it implements liquid encapsulation which might generate gas bubbles, in particular air bubbles, within the encapsulant and making it difficult to control the thickness of the encapsulant. As the module evolves in a vacuum, the gas bubbles could cause the photovoltaic module to burst when it is deployed outside the Earth's atmosphere in a space application due to a pressure difference between the gas bubbles and the exterior of the photovoltaic module. For a terrestrial application, the presence of bubbles is also detrimental because beyond simple aesthetics problems, the bubbles could induce a less good transmission of the solar radiation towards the photovoltaic cells if these bubbles have formed above the photovoltaic cells (the solar radiation might then partly be reflected). Moreover, the bubbles could also induce poorer thermal dissipation of the photovoltaic module, which might thus instantly cause a loss of efficiency of the photovoltaic cells. Another drawback of the presence of bubbles is that they could ultimately promote the delamination of the photovoltaic module.

Moreover, the American patent U.S. Pat. No. 9,842,952 B2 discloses another encapsulation solution based on silicones. The photovoltaic cells are first deposited over a first external layer. Then, a composition based on silicone and reinforcing fibres is positioned over the photovoltaic cells in order to form a second external layer. The use of reinforcing fibres allows controlling the diffusion of the silicone composition and avoiding the use of a support layer so as to reduce costs, production difficulties and manufacturing time. However, the use of such fibres in the silicone composition also generates additional constraints in comparison with the use of a simple silicone composition which are not necessarily desirable, for example in terms of additional manufacturing complexity, higher costs, possible problems of adhesion of the fibres to the silicone composition, or still of reduction in the transparency of the silicone composition, inter alia. The addition of fibres or another element in the encapsulant generally generates a greater mass, which is not desirable for a space application. In addition, some fibres such as carbon fibres could represent a risk of short-circuiting due to their higher electrical conductivity.

Thus, the use of silicone resins alone as encapsulation materials for space applications is a preferred solution. They could also be useful for terrestrial applications, in particular by allowing increasing the service life of solar modules from 25 to 40, and possibly 50 years. Such an improvement is primarily due to the absence of generation of acetic acid during the cross-linking process, unlike EVA, and a better thermal and ultraviolet stability. In addition, the chemistry of silicones is flexible enough to be able to accurately adjust the physico-chemical properties of the products, such as the refractive index, viscosity, hardness and tensile strength, and mass production of these materials is possible. In addition, due to their low Young's modulus and their low glass transition temperature, in the range of −50° C., their mechanical properties remain constant over a wide range of temperatures.

However, adhesives based on pure silicone are generally initially in a liquid state, which complicates their implementation. In particular, they are not compatible as such with vacuum lamination processes, unlike adhesives in the form of films. Thus, although the encapsulation of photovoltaic modules with silicone resins has been considered for more than thirty years in the prior art, there are still many challenges to be met in order to improve the reliability of this type of process. Hence, the main difficulties related to the use of silicone to encapsulate photovoltaic modules are: the deposition methods; the thickness control; the adhesion of all layers; the encapsulant creeping during a lamination process; the method used for crosslinking; the service life of the product once prepared; the presence of trapped air bubbles, voids or cavities; the optimisation of the composition to improve the properties of the polymer (viscosity, elasticity, transparency and hardness); the production at high volumes and at a reasonable cost.

### DISCLOSURE OF THE INVENTION

The invention aims to address at least partially the above-mentioned needs and the drawbacks relating to the implementations of the prior art.

Thus, an object of the invention, according to one of its aspects, is a method for manufacturing a photovoltaic module, comprising at least one photovoltaic cell, in particular a plurality of photovoltaic cells disposed side-by-side, between a first transparent layer forming a front face of the photovoltaic module and a second layer forming a rear face of the photovoltaic module, characterised in that it comprises:

1) a first step of depositing a first adhesive layer based on a crosslinkable polymer material over the first layer intended to form the front face of the photovoltaic module, and in depositing a second adhesive layer based on a crosslinkable polymer material over the second layer intended to form the rear face of the photovoltaic module,

2) a second step of carrying out a partial crosslinking of the two adhesive layers based on a crosslinkable polymer material to form two partially crosslinked adhesive layers,

3) a third step of depositing said at least one photovoltaic cell over one of the two partially crosslinked adhesive layers,

4) a fourth step of forming a multilayer stack, namely a stacking of the constituent layers of the photovoltaic module, by assembling one of the two partially crosslinked adhesive layers over the other one of the two partially crosslinked adhesive layers, which comprises said at least one photovoltaic cell, thereby enabling the encapsulation of the photovoltaic cell(s),

5) a fifth step of carrying out the lamination of the multilayer stack, and the completion of the crosslinking of the two partially crosslinked adhesive layers, so as to form a single and unique encapsulation layer of the photovoltaic cell(s).

Advantageously, the manufacturing method according to the invention therefore allows making a stack in parallel over the first layer forming the front face and over the second layer forming the rear face, depositing the photovoltaic cell(s) over one of the two faces, then assembling the two pre-crosslinked portions, i.e. partially crosslinked and prior to the lamination step which generally enables said crosslinking, and finally laminating the assembly. In this manner, it is possible to limit the inclusion of air between the front/rear barriers and the encapsulant, unlike solutions of the prior art providing for a stack made entirely from a single face. It is also possible to obtain a suitable, controlled and homogeneous final thickness of the encapsulant, and possibly different on the two faces where necessary. Advantageously, this final thickness is comprised between 40 and 200 microns, and the position of the cell(s) within the final encapsulant is not necessarily at the middle of this encapsulant.

Advantageously again, the invention therefore allows carrying out the encapsulation of photovoltaic modules using silicone-type adhesives, the crosslinking of which is initiated prior to the lamination.

By “crosslinkable polymer material”, it should be understood a polymer material adapted to be crosslinked, whose state could switch into a crosslinked state. In particular, a crosslinkable polymer material has a degree of crosslinking strictly lower than the gel point of this polymer material. In particular, the crosslinkable polymer material is in the liquid state. By “material in the liquid state”, it should be understood that the material has a tendency to flow due to the low cohesion of the molecules composing it. In particular, the liquid state of the crosslinkable polymer material is such that this crosslinkable polymer material has a viscosity preferably comprised between 1 Pa·s and 50 Pa·s at a temperature of 25° C. In the present description, the viscosity values are given at atmospheric pressure.

The manufacturing method according to the invention may also include one or more of the following features considered individually or in any possible technical combination.

Preferably, the first adhesive layer based on a crosslinkable polymer material and the second adhesive layer based on a crosslinkable polymer material may be identical. In particular, they may be based on the same crosslinkable polymer material.

Moreover, the first adhesive layer may be based on a crosslinkable polymer material in the liquid state and/or the second adhesive layer may be based on a crosslinkable polymer material in the liquid state.

Each adhesive layer based on a crosslinkable polymer material, deposited during the first step, namely the first adhesive layer and the second adhesive layer, may have a thickness comprised between 20 and 100 μm, preferably between 20 and 60 μm, and advantageously in the range of 50 μm, namely equal to 50 μm±5 μm. The first and second adhesive layers based on a crosslinkable polymer material may have different or identical thicknesses. The overall thickness of the first and second adhesive layers based on a crosslinkable polymer material is advantageously comprised between 40 and 200 μm.

In addition, the crosslinking rate implemented during the second step of partial crosslinking of the two adhesive layers based on a crosslinkable polymer material may be comprised between 40% and 70%, preferably between 50% and 60%, even more preferably between 50% and 55%. The crosslinking rate may vary within this range, depending on the used material and on the lamination parameters used later on.

The crosslinking rate could be measured by the DSC method (standing for “Differential Scanning calorimeter”), a relative measurement by calculation of the air under the crosslinking peak, according to the enthalpy method of the IEC 62788 standard adapted to silicone encapsulants: a temperature scan is carried out, from 40° C. to 200° C., of a fresh sample of encapsulant. This scan reveals the crosslinking peak. By calculating the air under the peak of the curve, the enthalpy of the total crosslinking reaction is obtained, i.e. the energy released by the exothermic crosslinking reaction. When the same measurement and the same calculation are carried out for a partially pre-crosslinked sample, the enthalpy value is lower than that of the fresh product, since it corresponds to the end of crosslinking. This is called residual enthalpy. The difference between the two enthalpies gives us the percentage of the crosslinking reaction performed during the pre-crosslinking.

Such a value of the crosslinking rate allows maximising the adhesion between the various layers, to enable the evacuation of air bubbles, as well as minimising the final thickness of the encapsulant. Thus, this value of the crosslinking rate corresponds to the best trade-off between adhesion, small thickness and evacuation of air bubbles.

Furthermore, the crosslinking time implemented during the second step of partial crosslinking of the two adhesive layers based on a crosslinkable polymer material may be comprised between 1 minute and 1 hour.

The crosslinking temperature implemented during the second step of partial crosslinking of the two adhesive layers based on a crosslinkable polymer material may be comprised between 50 and 150° C.

In particular, the crosslinking duration implemented during the second step of partial crosslinking of the two adhesive layers based on a crosslinkable polymer material may be comprised between 5 minutes and 15 minutes, and in that the crosslinking temperature implemented during the second step of partial crosslinking of the two adhesive layers based on a crosslinkable polymer material may be comprised between 90 and 110° C.

Moreover, the fifth lamination step may be carried out at a positive pressure comprised between 100 mbar and 1 bar, in particular between 500 mbar and 1 bar, still in particular between 800 mbar and 1 bar. Also, the chamber where the module is located is not necessarily under vacuum.

In addition, the fifth lamination step may comprise a pump-out for a duration comprised between 5 and 10 minutes.

Preferably, the crosslinkable polymer material may be selected from the family of silicones.

Furthermore, the said at least one photovoltaic cell (4) may be selected from among silicon-type cells, III-V semiconductors, CIGS (copper, indium, gallium, selenium), CdTe (cadmium telluride), organics, perovskites or multi-junctions of these types.

Moreover, advantageously, the adhesion layer (s) based on a crosslinkable polymer material is/are devoid of any reinforcing element, in particular of any reinforcing fibres, whether textile or not, intended in particular to limit the liquid flow of the crosslinkable polymer material.

### BRIEF DESCRIPTION OF THE DRAWINGS

The invention could be better understood upon reading the following detailed description, of a non-limiting example of implementation thereof, as well as upon examining the, schematic and partial, figures of the appended drawing, wherein:

FIG. 1 illustrates, schematically and in section, the first step of a method of manufacturing a photovoltaic module in accordance with the invention,

FIG. 2 illustrates, schematically and in section, the second step of the manufacturing method in accordance with the invention,

FIG. 3 illustrates, schematically and in section, the third step of the manufacturing method in accordance with the invention,

FIG. 4 illustrates, schematically and in section, the fourth step of the manufacturing method in accordance with the invention, and

FIG. 5 illustrates, schematically and in section, the fifth step of the manufacturing method in accordance with the invention.

In all of these figures, identical references may refer to identical or similar elements.

In addition, the different portions represented in the figures are not necessarily according to a uniform scale, to make the figures more readable.

### DETAILED DISCLOSURE OF PARTICULAR EMBODIMENTS

In the description of the example of implementation of the invention that will follow, the considered field of application is that of photovoltaic modules for space applications. Nonetheless, the invention also applies to photovoltaic modules intended for terrestrial applications.

Advantageously, the manufacturing method according to the invention enables encapsulation with a crosslinkable polymer material using two main steps of carrying out a partial crosslinking of the liquid encapsulant, and a lamination of the entirety of the formed stack.

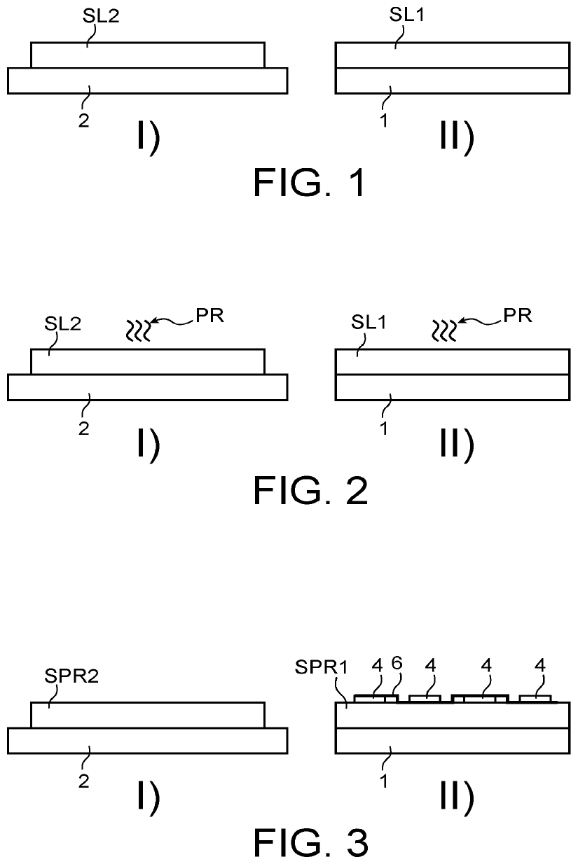

More particularly, as illustrated in FIG. 1, the method for manufacturing a photovoltaic module 10 in accordance with the invention firstly includes a first step 1) of forming a first sub-stack I) and a second sub-stack II).

The first sub-stack I) is formed by depositing a liquid adhesive layer SL2 based on a crosslinkable polymer material over a second layer 2 intended to form the rear face of the photovoltaic module 10.

The second sub-stack II) is formed by the deposition of a liquid adhesive layer SL1 based on a crosslinkable polymer material over a first layer 1 intended to form the front face of the photovoltaic module 10.

Preferably, the crosslinkable polymer material is selected from the family of silicones. Silicone has the advantage of being transparent, electrically insulating and features an environmental and thermal stability (i.e. little or no degradation related to humidity, oxygen or acids at temperatures varying between −200° C. and 200° C.). Moreover, silicone could improve the service life of the photovoltaic module 10 in comparison with an EVA encapsulant. Silicone prevents the formation of acetic acid, unlike EVA. Silicone has a better stability to ultraviolet radiation. The silicone chemistry is flexible enough to accurately adjust the physico-chemical properties (refractive index, viscosity, hardness, tensile strength, mechanics) of the encapsulant while enabling mass production. Because of the low Young's modulus of silicone and the low glass transition temperature (for example −50° C.) of silicone, the mechanical properties of the crosslinked silicone remain constant over a wide range of temperatures. With silicone, it is possible to encapsulate one or several photovoltaic cell(s) 4 for a space application at a temperature that could vary between −65° C. and +200° C. and could be used down to −200° C.

Afterwards, as illustrated in FIG. 2, a second step 2) is carried out by the partial crosslinking, schematised by PR in FIG. 2, of the two liquid adhesive layers SL1, SL2 to form, on the first sub-stack I), a second partially crosslinked adhesive layer SPR2, visible in FIG. 3, and, on the second sub-stack II), a first partially crosslinked adhesive layer SPR1, visible in FIG. 3.

The partial crosslinking PR of the liquid silicone allows increasing its viscosity and its mechanical strength, which then allows ensuring a minimum amount of encapsulant over and beneath the photovoltaic cells 4.

Next, as illustrated in FIG. 3, a third step 3) is implemented by the deposition of the photovoltaic cells 4 over the partially crosslinked first adhesive layer SPR1. Alternatively, the deposition could also be done over the second partially crosslinked adhesive layer SPR2, in other words at the rear face. This alternative could be particularly useful in the case where the rear face 2 includes a printed circuit with conductive tracks to which the photovoltaic cells 4 should be linked/connected. In this case, it is possible to protect the interconnection elements of the cells to make them accessible after the partial crosslinking phase.

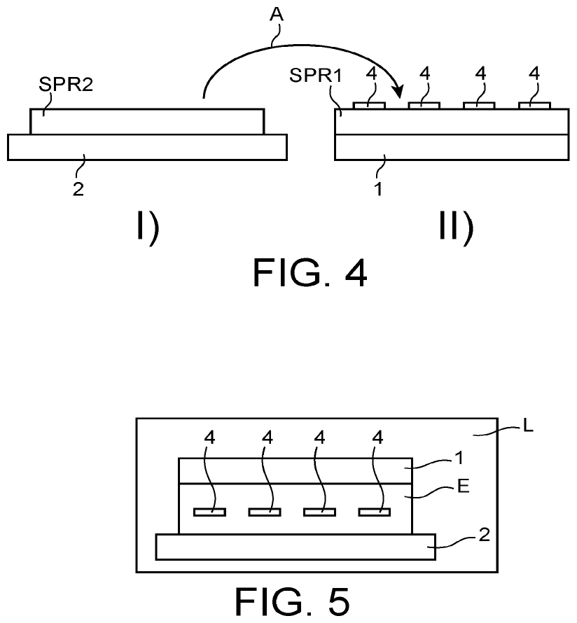

A fourth step 4) is then implemented, as visible in FIG. 4, of forming a multilayer stack, namely a stack of the constituent layers of the photovoltaic module 10, by assembling the first sub-stack I) over the second sub-stack II), schematised by the arrow A, the second partially crosslinked adhesive layer SPR2, devoid of photovoltaic cells 4, then lying above the first partially crosslinked layer SPR1 which comprises the photovoltaic cells 4.

Then, a fifth step 5), illustrated by FIG. 5, allows carrying out the lamination, schematised by the frame L, of the obtained assembly and the completion of the crosslinking of the two partially crosslinked adhesive layers SPR1, SPR2 to form a single and unique encapsulation layer E of the photovoltaic cells 4. It should be noted that, before this lamination step, it is also possible to turn the stack over so that the front face 1 is turned downwards.

Any crosslinkable polymer material referred to in the present description may include, in particular consist of, two components A and B. The component A is a base, for example of the PDMS (standing for polydimethylsiloxane) type. The component B contains a vulcanising agent, such as polysiloxane, and a catalyst to enable the polymer chains to branch to form a three-dimensional network so that the crosslinkable polymer material could, upon completion of its crosslinking, form a corresponding layer made of a solid and unmeltable material.

The crosslinkable polymer material used in the context of this manufacturing process may be selected from among: Sylgard® 184 from the company Dow Corning, Dow Corning® 93-500, Siltech® CR 12-63, Siltech® CR 13-46, Elastosil Company® RT 625 from the company Wacker, MAPSIL® 213 from the company MAP COATING, MAPSIL® 213B from the company MAP COATI NG, and MAPSIL® QS 1123 from the company MAP COATING.

A particular embodiment will now be described. In this example, it is proceeded with the preparation of the front face 1 at first.

The surface of the front face 1 is prepared using a physical surface treatment, for example of the plasma or corona type, followed by a deposition of a primer to facilitate hooking of the crosslinkable polymer material. It should be noted that the first layer 1 forming the front face is advantageously transparent, and may be glass or a polymer such as transparent polyimide, polyethylene terephthalate (PET), polyethylene naphthalate (PEN), or else a fluorinated film such as fluoroethylene propylene (FEP), ethylene tetrafluoroethylene (ETFE), ethylene chlorotrifluoroethylene (ECTFE), polyvinylidene fluoride (PVDF), or else polyetheretherketone (PEEK), inter alia.

Afterwards, a deposition of a liquid silicone layer SL1 is carried out over this front face 1. This adhesive may be deposited by any coating means, with a brush, with a roller, with a device called “Doctor Blade”, or else by spraying. The thickness and the depositing means are adapted to the use. For example, the thickness is comprised between 20 and 100 μm. The less viscous the adhesive, the easier it will be to make thin films. An excessively small or excessively large amount of adhesive would cause the apparition of air bubbles or voids in the module 10 upon crosslinking.

Then, the adhesive layer is degassed in a vacuum bell for a period comprised between 1 and 20 minutes, preferably comprised between 5 and 10 minutes.

Afterwards, the partial crosslinking of this adhesive layer SL1 is carried out to obtain the pre-crosslinked layer SPR1. The partial crosslinking is carried out with the desired means: heating in a furnace or oven, heating by infrared or ultraviolet, inter alia.

Afterwards, the interconnected photovoltaic cells 4 are positioned, for example by means of a ribbon 6 as shown in FIG. 3, over the pre-crosslinked layer SPR1, the cells possibly being coated with a primer to maximise adhesion. These cells 4 may be based on silicon, based on III—V type materials, CIGS (copper, indium, gallium, selenium), CdTe (cadmium telluride), organics, perovskites or multi-junctions of these types.

Concomitantly, the rear face 2 is prepared through a process symmetrical to that applied for the front face 1. Nonetheless, it should be noted that the partial crosslinking parameters and the thicknesses could be identical, or not, for the front face 1 and the rear face 2.

Thus, the surface of the rear face 2 is prepared using a physical surface treatment, for example of the plasma or corona type, followed by a deposition of a primer to facilitate hooking of the crosslinkable polymer material. This rear face 2 is not necessarily transparent. It may be a composite material support, for example of the carbon/aluminum honeycomb type, or a foam, glass, a polymer film or else a fabric, inter alia.

Afterwards, a deposition of a liquid silicone layer SL2 over this rear face 2. This adhesive may be deposited by any coating means, with a brush, with a roller, with a device called “Doctor Blade” or else by spraying. The thickness and the deposition means are adapted to the use. For example, the thickness is comprised between 20 and 100 μm. It should be so that the less viscous the adhesive, the easier it will be to make thin films. An excessively small or excessively large amount of adhesive will cause the apparition of air bubbles and voids in module 10 upon crosslinking.

Then, the adhesive layer is degassed in a vacuum bell for a period comprised between 1 and 20 minutes, preferably comprised between 5 and 10 minutes.

Afterwards, the partial crosslinking of this adhesive layer SL2 is carried out to obtain the pre-crosslinked layer SPR2. The partial crosslinking is carried out with the desired means: heating in a furnace or oven, heating by infrared or ultraviolet, inter alia.

Preferably, the duration of the partial crosslinking step is comprised between 5 and 15 minutes, for example in the range of 5 to 7 minutes, and the temperature is comprised between 90° C. and 110θ C., for example 100° C.

At this stage, it is then proceeded with the assembly of the two portions and with the vacuum lamination. Thus, the two portions I) and II) are assembled so as to obtain the stack of layers 1, SPR1, 4, SPR2, 2. Afterwards, they are laminated under vacuum.

The lamination program comprises a pump-out step for 5 to 10 minutes, followed by a heating step during which a positive pressure comprised between 100 mbar and 1 bar, preferably between 500 mbar and 1 bar, or possibly 800 mbar and 1 bar, is applied. The temperature and the duration required for complete crosslinking depend on the characteristics of the adhesive. For example, to crosslink a Sylgard® 184 formulation, a lamination at 140° C. comprising 5 minutes of pumping out and 15 minutes at 1 bar is suitable.

It should be noted that, in the case where the difference in the coefficient of thermal expansion is high between the different materials, it might be judicious to lower the temperature of the lamination and therefore increase its duration. For Sylgard® 184, a lamination at 80° with 5 minutes of pumping out and 50 minutes at 1 bar is also possible. In particular, this allows limiting the thermomechanical stresses exerted on the different materials forming the photovoltaic module 10 during manufacture, and thus limiting the residual internal stresses after manufacture which could go so far as to create undesirable curvatures of the module.

Of course, the invention is not limited to the embodiment that has just been described. Various modifications could be made thereto by a person skilled in the art.

1. A method for manufacturing a photovoltaic module,
comprising at least one photovoltaic cell between a first transparent layer forming a front face of the photovoltaic module and a second layer forming a rear face of the photovoltaic module, comprising:
1) a first step of depositing a first adhesive layer based on a crosslinkable polymer material over the first layer intended to form the front face of the photovoltaic module, and in depositing a second adhesive layer based on a crosslinkable polymer material over the second layer intended to form the rear face of the photovoltaic module,
2) a second step of carrying out a partial crosslinking of the two adhesive layers based on a crosslinkable polymer material to form two partially crosslinked adhesive layers,
3) a third step of depositing said at least one photovoltaic cell over one of the two partially crosslinked adhesive layers,
4) a fourth step of forming a multilayer stack by assembling one of the two partially crosslinked adhesive layers over the other one of the two partially crosslinked adhesive layers, which comprises said at least one photovoltaic cell,
5) a fifth step of carrying out the lamination of the multilayer stack, and the completion of the crosslinking of the two partially crosslinked adhesive layers,
the crosslinking rate implemented during the second step of partial crosslinking of the two adhesive layers based on a crosslinkable polymer material being comprised between 40% and 70%.

2. The method according to claim 1, characterised in wherein each adhesive layer based on a crosslinkable polymer material, deposited during the first step, has a thickness comprised between 20 and 100 μm.

3. The method according to claim 1, wherein the crosslinking rate implemented during the second step of partial crosslinking of the two adhesive layers based on a crosslinkable polymer material is comprised between 50% and 60%

4. The method according to claim 1, wherein the crosslinking time implemented during the second step of partial crosslinking of the two adhesive layers based on a crosslinkable polymer material is comprised between 1 minute and 1 hour.

5. The method according to claim 1, wherein the crosslinking temperature implemented during the second step of partial crosslinking of the two adhesive layers based on a crosslinkable polymer material is comprised between 50 and 150° C.

6. The method according to claim 4, wherein the crosslinking duration implemented during the second step of partial crosslinking of the two adhesive layers based on a crosslinkable polymer material is comprised between 5 minutes and 15 minutes, and wherein the crosslinking temperature implemented during the second step of partial crosslinking of the two adhesive layers based on a crosslinkable polymer material is comprised between 90 and 110° C.

7. The method according to claim 1, wherein the fifth lamination step is carried out at a positive pressure comprised between 100 mbar and 1 bar.

8. The method according to claim 1, wherein the fifth lamination step comprises a pump-out for a duration comprised between 5 and 10 minutes.

9. The method according to claim 1, wherein the crosslinkable polymer material is selected from the family of silicones.

10. The method according to claim 1, wherein the said at least one photovoltaic cell can be selected from among silicon-type cells, III-V semiconductors, CIGS (copper, indium, gallium, selenium), CdTe (cadmium telluride), organics, perovskites or multi junctions of these types.

11. The method according to claim 1, characterised in that wherein the first adhesive layer based on a crosslinkable polymer material and the second adhesive layer based on a crosslinkable polymer material are based on the same crosslinkable polymer material.

12. The method according to claim 1, wherein the first adhesive layer is based on a crosslinkable polymer material in the liquid state and/or wherein the second adhesive layer is based on a crosslinkable polymer material in the liquid state.
